(19) United States
(12) Patent Application Publication
(10) Pub. No.: US 2025/0199559 A1
(43) Pub. Date: Jun. 19, 2025

(54) LOW-POWER AND FAST WAKE-UP BAND-GAP VOLTAGE REFERENCE CIRCUIT

(71) Applicant: Weebit Nano Ltd., Hod Hasharon (IL)

(72) Inventor: Avi FISHER, Zur Yizhak (IL)

(73) Assignee: Weebit Nano Ltd., Hod Hasharon (IL)

(21) Appl. No.: 18/978,298

(22) Filed: Dec. 12, 2024

Related U.S. Application Data
(60) Provisional application No. 63/612,100, filed on Dec. 19, 2023.

(51) Int. Cl. G05F 3/26; H03K 17/22; H03K 17/30

(52) U.S. Cl. CPC G05F 3/262; H03K 17/223; H03K 17/302; H03K 2217/0081

(57) ABSTRACT

The low-power fast wake-up band-gap reference voltage circuit operates in three phases: dormant, wake-up, and steady-state phases. The circuit enters wake-up subsequent to receipt of an enable signal which causes a one-shot timer to generate a slew enable signal pulse having a predetermined period. To a band-gap voltage reference circuitry comprising an operational amplifier, there is connected, at the wake-up phase, a boost circuitry, operative under the control of the slew enable signal that connects one or more of the one or more boost circuits to a band-gap voltage reference. Thereby, during the brief wake-up phase, more current is consumed to accelerate the response of the circuit. Upon completion of the wake-up phase the boost circuitry is disconnected under the control of the slew enable signal and for as long as the enable signal is active, the circuit is operative in a low-power mode.

### CROSS-REFERENCE TO RELATED APPLICATIONS

The application claims the benefit of U.S. Provisional Application No. 63/612,100 filed on Dec. 19, 2023, the contents of which are hereby incorporated by reference.

### TECHNICAL FIELD

The present disclosure generally relates to the field of analog integrated circuits, particularly to band-gap voltage reference circuits widely used in Very Large-Scale Integration (VLSI) chips. More specifically, such circuits serve as a stable and precise reference voltage source with minimal dependency on process variations, supply voltage fluctuations, and temperature changes (PVT variations).

### BACKGROUND

Band-gap voltage reference circuits are essential analog building blocks used extensively in Very Large-Scale Integration (VLSI) chip design. These circuits are responsible for generating a reference voltage that remains relatively constant in the face of diverse operating conditions, making them indispensable for ensuring the accurate functionality of analog and mixed-signal components within integrated circuits. The reference voltage provided by band-gap circuits is often used as a foundation for creating various other analog by-products, including reference voltages and biasing currents, which have widespread application throughout the chip.

One significant challenge associated with conventional band-gap circuits is their slow wake-up time, which is the time required for these circuits to become fully operational and stable after power is applied. In most analog and mixed-signal chip designs, band-gap circuits are the first blocks to be enabled during chip wake-up, with other analog and/or mixed-signal blocks often held in a waiting state until the band-gap circuit is fully operational and stable.

The wake-up time of a band-gap circuit is closely linked to its power consumption. Generally, faster wake-up times necessitate higher power consumption, which may conflict with stringent power budgets that must be adhered to in many applications, in particular at steady-state operation. As a result, designers are often faced with the challenge of optimizing wake-up times while maintaining power consumption within acceptable limits.

Conventional band-gap circuits, like the one shown in FIG. 1, typically comprise several key components, including bipolar transistors 110-1 and 110-2, an operational amplifier 120, comprising a differential first stage 122 and an amplification second stage 124, compensation capacitors 140-1 and 140-2, a current mirror comprised of p-channel metal oxide semiconductor (MOS) devices 150-1 and 150-2, and poly resistors 130-1, 130-2 and 130-3. These components work in unison to create a stable voltage reference 160 that exhibits a band-gap voltage characteristic, which allows it to be minimally affected by variations in process parameters, in particular the process corners, Fast-Fast, Slow-Slow, Slow-Fast and Fast-Slow, supply voltage, and temperature.

The wake-up time of a band-gap circuit is primarily determined by the bandwidth of the analog closed-loop system within the circuit. Basically, the bandwidth is a measure of the op-amp's ability to respond to input signals across a specified frequency range. This closed-loop system is influenced by the operational amplifier's 120 bandwidth and the size of the compensation capacitors 140 used to stabilize the system. The bandwidth of the operational amplifier 120 defines how fast the circuit 100 can respond to an activation of an ENABLE signal (not shown) that causes the circuit 100 to wake-up, while the size of the compensation capacitors 140 influences the stability and transient response of the circuit. That is, the operation amplifier's 120 ability to respond to rapid changes in input voltage, known as the slew rate, is related to bandwidth. A higher slew rate often corresponds to a higher bandwidth capability.

The wake-up time and power consumption of conventional band-gap circuits are directly interrelated, presenting a challenge to designers who seek to balance the need for fast wake-up time with efficient steady-state power consumption. Achieving a rapid wake-up time often involves sacrificing power efficiency during the entire operational time of the band-gap voltage reference circuit, which can be problematic in applications with stringent power constraints. On the other hand, low-power implementation results in a long slew time, i.e., the time during which the voltage of the circuit changes from its inactive value to its desired level.

In view of the foregoing challenges and limitations associated with conventional band-gap voltage reference circuits, there exists a need for innovative approaches that enable the design of band-gap circuits with improved wake-up times while maintaining power consumption within acceptable limits.

### SUMMARY

A summary of several example embodiments of the disclosure follows. This summary is provided for the convenience of the reader to provide a basic understanding of such embodiments and does not wholly define the breadth of the disclosure. This summary is not an extensive overview of all contemplated embodiments, and is intended to neither identify key or critical elements of all embodiments nor to delineate the scope of any or all aspects. Its sole purpose is to present some concepts of one or more embodiments in a simplified form as a prelude to the more detailed description that is presented later. For convenience, the term “some embodiments” or “certain embodiments” may be used herein to refer to a single embodiment or multiple embodiments of the disclosure.

Certain embodiments disclosed herein include a low-power fast wake-up band-gap reference voltage circuit comprises: a one-shot timer that generates a slew enable signal pulse for a predetermined period of time upon receipt of an enable signal; a band-gap voltage reference circuitry comprising an operational amplifier communicatively connected to the one-shot timer, a current mirror circuitry, a plurality of compensation capacitors, and a plurality of resistors, wherein the band-gap voltage reference circuitry is adapted to operate at a dormant power consumption level or at a steady-state power consumption level when providing a reference voltage after activation of the enable signal, wherein the steady-state power consumption is higher than the dormant power consumption; and, a boost circuitry communicatively connected to the band-gap voltage reference circuitry and further communicatively connected to the one-shot timer, wherein the boost circuitry comprises one or more boost circuits that upon activation of the one-shot slew enable signal causes a connection of one or more of the one or more boost circuits to the band-gap voltage reference, that together with other circuits of the band-gap voltage reference circuitry operate at a wake-up power consumption level that is higher than the steady-state power consumption level, wherein the low-power fast wake-up band-gap reference voltage circuit is configured for a fast wake-up at the wake-up power consumption level, and, wherein the low-power fast wake-up band-gap reference voltage circuit operates at the steady-state power consumption level upon deactivation of the one-shot slew enable signal that results in disconnect of the boost circuitry.

Certain embodiments disclosed herein also include a method of operation of a low-power fast wake-up band-gap reference voltage circuit comprises: operating the low-power fast wake-up band-gap reference voltage circuit at a dormant power consumption level; receiving by the low-power fast wake-up band-gap reference voltage circuit an enable signal; supplying a wake-up power to the low-power fast wake-up band-gap reference voltage circuit upon receipt of the enable signal; generating a pulse signal of a first pulse width upon receipt of the enable signal; connecting under control of the pulse and for a duration of the first pulse width a boost circuitry of the low-power fast wake-up band-gap reference voltage circuit that comprises one or more boost circuits that cause the low-power fast wake-up band-gap reference voltage circuit to operate at the wake-up power level consumption that is higher than the wake-up level of power consumption; and, disconnecting the boost circuitry under control of the pulse signal so that the low-power fast wake-up band-gap reference voltage circuit consumes power at a steady-state level of power consumption which is lower than the wake-up power consumption and higher than the dormant power consumption.

### BRIEF DESCRIPTION OF THE DRAWINGS

The subject matter disclosed herein is particularly pointed out and distinctly claimed in the claims at the conclusion of the specification. The foregoing and other objects, features, and advantages of the disclosed embodiments will be apparent from the following detailed description taken in conjunction with the accompanying drawings.

FIG. 1 illustrates a configuration of a conventional band-gap circuit.

FIG. 2A is a schematic diagram of a low-power and fast wake-up band-gap reference voltage circuit according to an embodiment.

FIG. 2B is a detailed schematic diagram of a low-power and fast wake-up band-gap reference voltage circuit according to an embodiment.

FIG. 2C is a timing diagram for wake-up activation of a low-power and fast wake-up band-gap reference voltage circuit according to an embodiment.

FIG. 3 is a circuit diagram of an enhanced operational amplifier of a low-power and fast wake-up band-gap reference voltage circuit according to an embodiment.

FIG. 4 is a compensation circuit for a low-power and fast wake-up band-gap reference voltage circuit according to an embodiment.

FIG. 5 is a simulation plot of an output voltage of a conventional band-gap reference voltage circuit versus a low-power and fast wake-up band-gap reference voltage circuit according to an embodiment.

FIG. 6 is a simulation plot at a slew period with and without a compensation circuitry of an output voltage of a low-power and fast wake-up band-gap reference voltage circuit according to an embodiment.

FIG. 7 is a flowchart of an operation of a low-power and fast wake-up band-gap reference voltage circuit according to an embodiment.

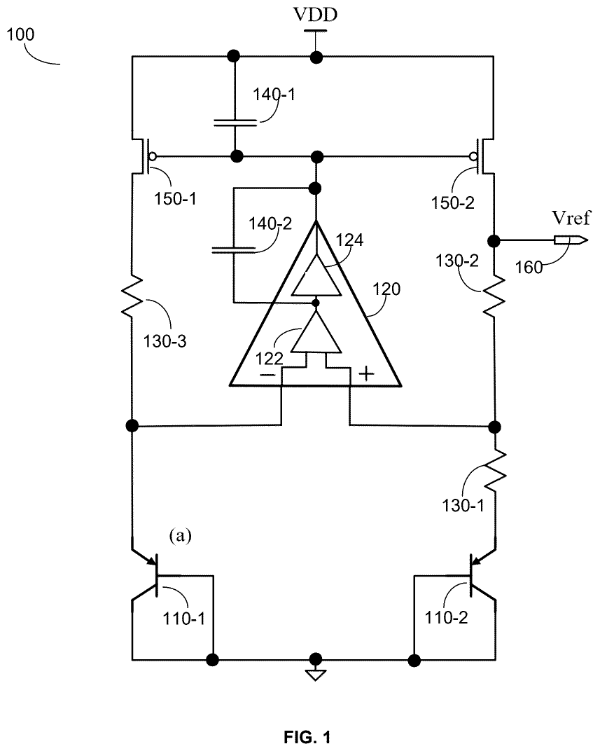

### DETAILED DESCRIPTION

It is important to note that the embodiments disclosed herein are only examples of the many advantageous uses of the innovative teachings herein. In general, statements made in the specification of the present application do not necessarily limit any of the various claims. Moreover, some statements may apply to some inventive features but not to others. In general, unless otherwise indicated, singular elements may be in plural and vice versa with no loss of generality. In the drawings, like numerals refer to like parts through several views.

The low-power fast wake-up band-gap reference voltage circuit operates in three phases: dormant, wake-up, and steady-state phases. The circuit enters wake-up subsequent to receipt of an enable signal which causes a one-shot timer to generate a slew enable signal pulse having a predetermined period, which is significantly shorter and negligible, for example, less than 10%, when compared to the required wake-up time of the low-power fast wake-up band-gap reference voltage circuit. To a band-gap voltage reference circuitry comprising an operational amplifier, there is connected, at the wake-up phase, a boost circuitry operative under the control of the slew enable signal that connects one or more of the one or more boost circuits to a band-gap voltage reference. Thereby, during the brief wake-up phase, more current is consumed to accelerate the response of the circuit and increase the bandwidth of the operational amplifier. Upon completion of the wake-up phase, the boost circuitry is disconnected under the control of the slew enable signal and, for as long as the enable signal is active, the circuit is operative in a low-power mode.

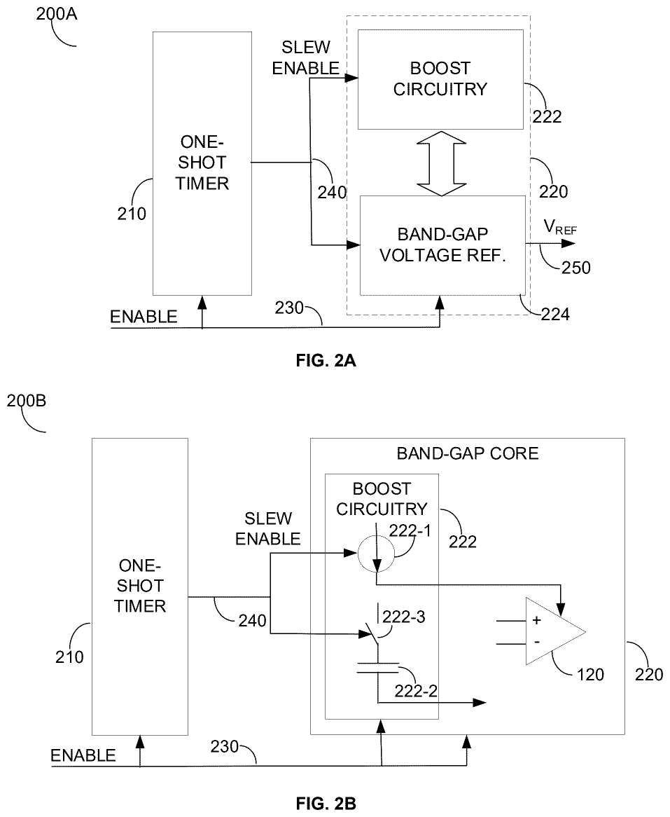

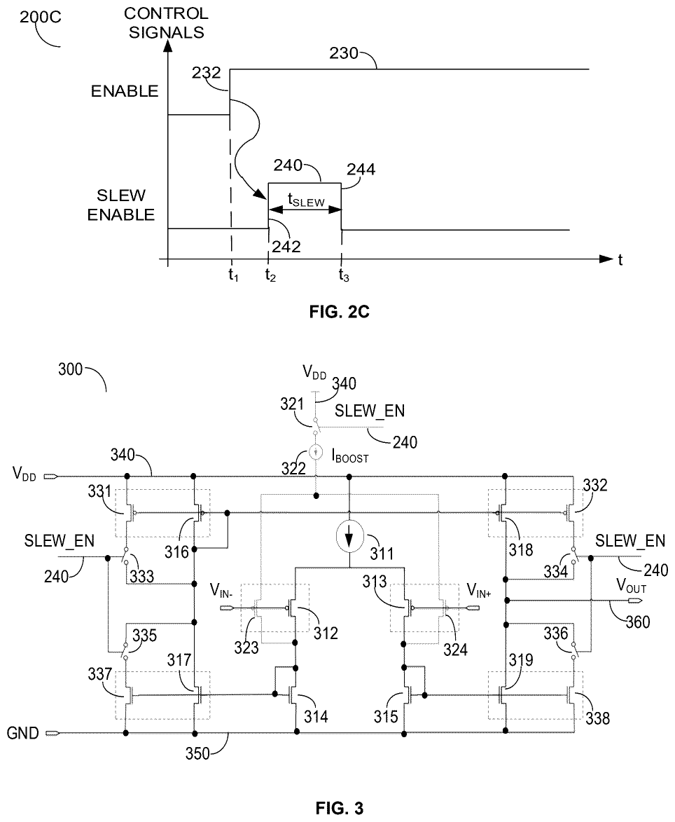

FIG. 2A depicts an example schematic diagram of a low-power and fast wake-up band-gap reference voltage circuit 200A according to an embodiment. When it is necessary to operate in a low-power mode during steady-state operation of a voltage reference circuit, there is a major challenge to be overcome, and that is the slow response time until the voltage reference stabilizes to its desired operating voltage. In many applications this is undesirable and hence the low-power and fast wake-up band-gap reference voltage circuit 200A provides a solution to the problem by handling the transient period, i.e., the period until the circuit wakes up, differently from the steady-state period, during which the circuit supply the voltage reference. Typically, the voltage reference circuit is not active until such time that an enable signal is provided, such as ENABLE signal 230. The operation of the ENABLE 230 is shown and discussed in FIG. 2C and associated text.

The low-power and fast wake-up band-gap reference voltage circuit 200A includes a one-shot timer 210, and an enhanced band-gap core 220. The band-gap core 220 includes a boost circuitry 222 and a band-gap voltage reference circuit 224. The one-shot timer 210, is configured to generate a SLEW ENABLE signal 240 in response to receiving an activation signal ENABLE 230. The SLEW ENABLE signal 240 one-shot in response to the ENABLE 230 is shown and discussed in FIG. 2C and associated text.

The boost circuitry 222, communicatively connected to the band-gap voltage reference circuit 224, connects to the band-gap voltage reference circuit 224 under the control of the SLEW ENABLE signal 240 thereby changing the response characteristics of the band-gap voltage reference circuit 224. Specifically, and as further explained herein, the boost circuitry 222 accelerates the response time of the band-gap voltage reference circuit 224 during the period where the SLEW ENABLE 240 is active. This allows the band-gap voltage reference circuit 224 to output VREF 250 as a stable output voltage with a fast wake-up time, without degrading the low-power performance of the low-power and fast wake-up band-gap reference voltage circuit 200A at steady-state, i.e., after the one-shot SLEW ENABLE 240 has deactivated. For the purpose of acceleration, different subcircuits may be used, for example, but not by way of limitation, current sources, and networks including passive components such as resistors and capacitors.

One of ordinary skill in the art would readily appreciate that while the description discusses connecting of boost circuits during the activation period of SLEW ENABLE 240, it is possible that rather than connecting circuits for this period, other circuits may be disconnected. It should be further appreciated by those of ordinary skill in the art that, while active high signals 230 and 240 are described, active low signals may be used without departing from the scope of the disclosed embodiments. In yet another embodiment, the one-shot timer 210 may be programmable, i.e., to define the time span in which the SLEW ENABLE 240 is active.

FIG. 2B is an example detailed schematic diagram of a low-power and fast wake-up band-gap reference voltage circuit 200B according to an embodiment. Specifically, it shows the types of boost circuits that may include the boost circuitry 222. For example, but not by way of limitation, a current source 222-1 is controlled by the SLEW ENABLE signal 240. During steady-state operation the current source 222-1 is inactive, however, during the active state of the SLWE ENABLE signal 240 current is provided to enhance the performance of, for example, the operational amplifier 120, resulting in a faster slew time. That means that the band-gap reference voltage circuit 200B will reach the desired operational reference voltage faster than in the case where no such boost is available. One of skill in the art would appreciate that, in an embodiment, the amount of current supplied by the current source 222-1 is programmable.

The boost circuitry 222 may further comprise a passive boost circuitry, for example, a capacitor 222-2. The capacitor 222-2 may be connected or disconnected, for example, under control of switch 222-3, from the circuitry that includes the low-power and fast wake-up band-gap reference voltage circuit 200B under the control of the SLEW ENABLE signal 24,0. By connecting or disconnecting this passive circuit the characteristics of the response of the low-power and fast wake-up band-gap reference voltage circuit 200B changes. According to the disclosed embodiments, it allows for a fast wake-up while the SLEW ENABLE signal 240 is active, at the price of spending additional power, while at steady-state, while the SLEW ENABLE signal 240 is inactive, operating the low-power and fast wake-up band-gap reference voltage circuit 200B at a low-power mode.

FIG. 2C is an example timing diagram 200C for a wake-up activation of a low-power and fast wake-up band-gap reference voltage circuit according to an embodiment. For simplicity, the reference number of FIG. 2A and 2B are used. At time t₁, the ENABLE signal 230 changes 232 from its inactive state to its active state. The ENABLE signal 230 is provided to the one-shot timer 210 and as a result, a pulse is generated at t₂ where the SLEW ENABLE signal 240 changes 242 at t₂ from an inactive state to an active state for a predetermined period t_{SLEW}. After the predetermined period t_{SLEW}, the SLEW ENABLE signal 240 changes 244 at t₃ back from its active state to its inactive state. In an example embodiment, t_{SLEW} may have a range between 1 μs (microsecond) and 3 μs, however, this range should not be viewed as limiting upon the disclosed embodiments, and other predetermined time period of t_{SLEW} may be used without departing from the scope of the disclosed embodiments. One of ordinary skill in the art would readily appreciate that while active high signals are used in the description herein, active low signals may be used without departing from the scope of the disclosed embodiments. In an embodiment, the time delta between t₁ and t₂ may be constant, while in another embodiment, it may be programmable, i.e., it may be readily changed. In yet another embodiment, the time delta between t₂ and t₃, which determines t_{SLEW}, may be constant, while in another embodiment, t_{SLEW} may be programmable.

During the slew phase, the low-power and fast wake-up band-gap reference voltage circuits 200A or 200B speed is boosted as a result of the effect of the control of the boost circuits of the boost circuitry 222. A current source, for example current source 222-1, provides extra current to the loop amplifier, for example operational amplifier 120, which extends the bandwidth of the amplifier. Certain passive capacitors, for example, capacitor 222-2 may be connected or disconnected for the performance boost necessary to accelerate the wake-up of the low-power and fast wake-up band-gap reference voltage circuits 200A or 200B. In an embodiment, further described herein, additional filtering capacitors are connected or disconnected for the purposes of suppressing oscillations resulting from the high current levels during boost, where the high current level can reach double or triple the current at steady-state mode. Overall, as a result of the described solution, wake-up time improves dramatically. While overall current consumption of the low-power and fast wake-up band-gap reference voltage circuits 200A or 200B rises during t_{SLEW}, this is a tradeoff that supports both the required wake-up time and the need for low-power consumption at steady-state operation.

FIG. 3 is an example circuit diagram of an enhanced operational amplifier 300 of a low-power and fast wake-up band-gap reference voltage circuit according to an embodiment. Power is supplied to the operational amplifier 300 by V_{DD} 340 and ground (GND) 350. The core of the operational amplifier 300 includes a current source 311 and transistors 312, 313, 314, 315, 316, 317, 318, and 319. In an embodiment, each metal oxide semiconductor field effect transistor (MOSFET) has an n-channel or a p-channel as the case may be and further depicted in FIG. 3. The transistors (312, 313, 314, 315, 316, 317, 318, and 319) form a conventional operational transconductance amplifier (OTA).

To enhance the performance of the OTA in accordance with the embodiment, a current source 322 which provides additional current to the circuit during the period t_{SLEW} is added. Such addition is done by connecting the current source 322 via a switch 321, controlled by the SLEW ENABLE signal 240. The current is provided through the MOSFETs 323 and 324 which are positioned essentially in parallel to the MOSFETs 312 and 313, respectively. MOSFETs 323 and 324 further receive V_{IN-} and V_{IN+} respectively, just like their respective MOSFETs 312 and 313.

During t_{SLEW} MOSFETs 331, 332, 337, and 338 are connected in parallel to MOSFETs 316, 318, 317 and 319 respectively. This assists in carrying excess current at the output devices, aimed for the enhanced operational amplifier 300. It further avoids signal clipping and supports a faster response loop, in order to control that, switches 333, 334, 335, and 336 connect or disconnect MOSFETs 331, 332, 337, and 338 respectively, each under the control of the SLEW ENABLE signal 240.

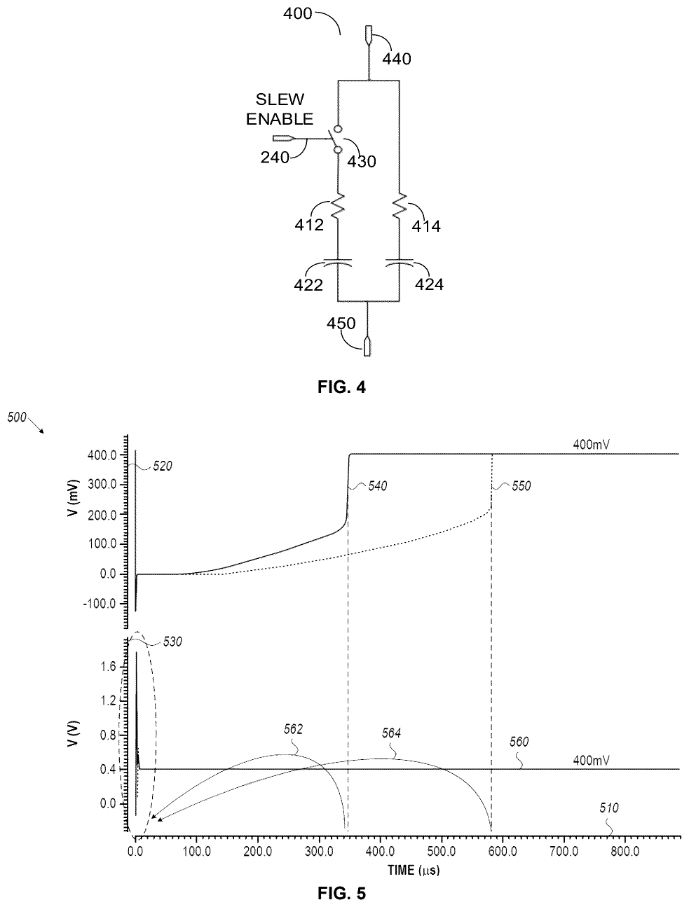

FIG. 4 is an example compensation circuit 400 for a low-power and fast wake-up band-gap reference voltage circuit, e.g. 200A or 200B, according to an embodiment. A network of passive components may change its characteristics exhibited between the network ports 440 and 450, under the control of a switch 430. The switch 430 is open or closed under the control of the SLEW ENABLE signal 240. The passive component network 400 includes a resistor 414 connected in series with a capacitor 424 and continuously connected between the ports 440 and 450. The passive component network 400 further includes a resistor 412 connected in series with a capacitor 422 and a switch 430. The switch 430 connects the resistor 412 and capacitor 422 between port 440 and port 450 when closed and disconnects them when open. As may be necessary, one or more compensation circuits 400 may be used to decrease the wake-up time of the low-power and fast wake-up band-gap reference voltage circuit, e.g. 200A or 200B, and suppress oscillations occurring during t_{SLEW}, as further explained herein. Other compensation circuit topologies may be used for the purpose of providing the prescribed benefits for each of the wake-up periods and the steady-state periods of the low-power and fast wake-up band-gap reference voltage circuit, e.g., 200A or 200B.

FIG. 5 is a simulation plot 500 of an output voltage of a standard band-gap reference voltage circuit versus a low-power and fast wake-up band-gap reference voltage circuit according to an embodiment. A standard band-gap reference voltage circuit refers to a conventional configuration of a band-gap reference voltage circuit. The horizontal axis 510 denotes time while the vertical axes 520 and 530 denote the output voltage for the prior art band-gap reference voltage circuit (graphs 540 and 550) and the low-power and fast wake-up band-gap reference voltage circuit (graph 560), respectfully. The graphs 540 and 550 of a standard circuit show that from the enable signal activated at time t=10 ns (nanoseconds), there are 350 μs until the faster standard circuit reaches the desired 400 mV. In the case of the slower standard circuit, no less than 580 μs pass before the desired 400 mV is reached. In an embodiment, V_{DD} is connected to the enhanced operational amplifier 300, for example at t=0 ns, after which the ENABLE signal is applied at t=10 ns. Hence, a sequence of first providing power to the enhanced operational amplifier 300 takes place, thereafter the ENABLE signal 230 is activated, and the wake-up acceleration begins according to the disclosed embodiments.

Configuring each of the original circuits used for the simulations that produced the graphs 540 and 560, the response of the low-power and fast wake-up band-gap reference voltage circuit, e.g., 200A or 200B disclosed herein provides a dramatic improvement. As shown by arrows 562 and 564, the slew time of the circuits shown by graphs 540 and 550 reach, 562 and 564, respectively, the desired output voltage 560 of 400 mV within a few μs, or a two-order of magnitude improvement in wake-up time over the standard circuits of a known art.

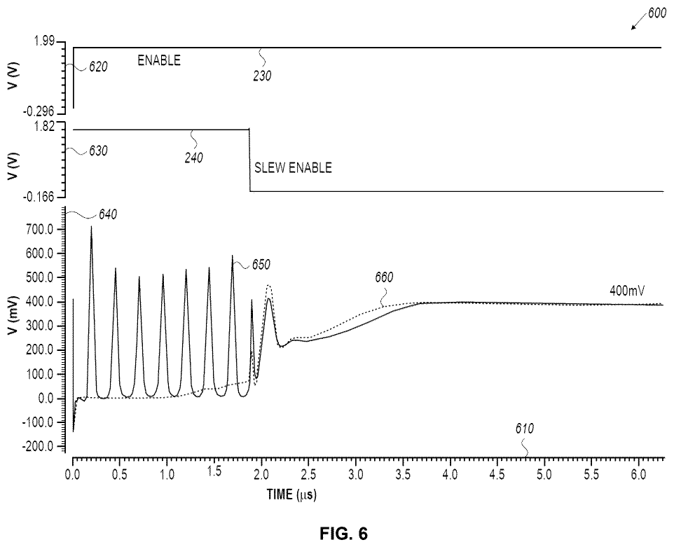

FIG. 6 is a simulation plot 600 at a slew period with 660 and without 650 compensation circuitry of an output voltage of a low-power and fast wake-up band-gap reference voltage circuit according to an embodiment. The horizontal axis 610 denotes time, extending to around 6 μs. In comparison, time axis 510 of FIG. 5 extends some 800 μs. The vertical axes 620, 630, and 640 denote output voltages for the ENABLE signal 230, SLEW ENABLE signal 240, and the low-power and fast wake-up band-gap reference voltage circuit 660, respectively. At t=10 ns the ENABLE signal 230 changes from its inactive state to its active state and as a result, the one-shot timer 210 responds with a pulse of the SLEW ENABLE signal 240 that changes from its inactive state to its active state and remains there for a period of 2 μs before returning to its inactive state.

The graph 650 shows certain oscillations during t_{SLEW} which cease upon the deactivation of the SLEW ENABLE signal 240. To suppress these oscillations, a filter may be connected to the output of the OTA at V_{OUT} 360, and/or at any other compensation nets within the enhanced operational amplifier 300, using, for example, but not by way of limitation, a suppression passive network that is shown in FIG. 4. As shown by graph 660, the wake-up time of a suppressed versus non-suppressed circuit is minimal, at less than 1 μs, where the suppressed circuit provides improved performance over the non-suppressed circuit.

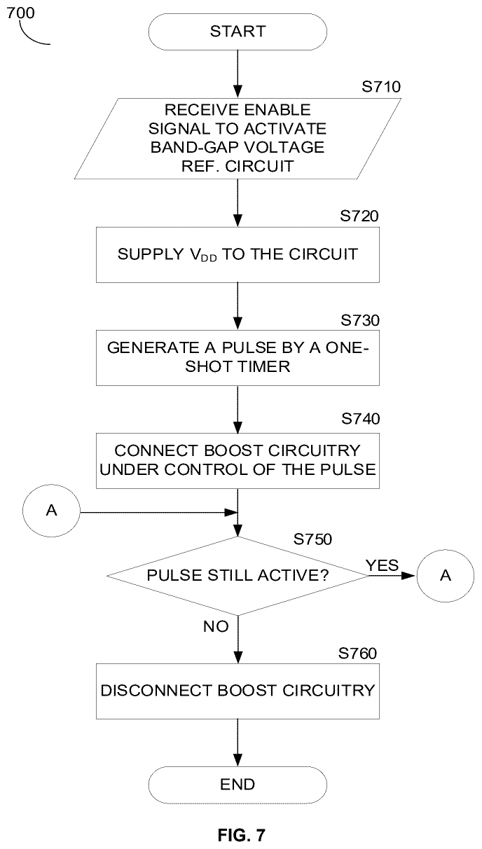

FIG. 7 is an example flowchart 700 depicting an operation of a low-power and fast wake-up band-gap reference voltage circuit according to an embodiment. The flowchart 700 describes the operations that take place in order to get the low-power and fast wake-up band-gap reference voltage circuit, e.g., 200A or 200B, working from the application of the initial power supply voltage V_{DD}, when the ENABLE signal 230 is applied, the activation of the SLEW ENABLE signal 240 by a one-shot timer, for example one-shot timer 210, the connection of the boost circuitry, for example, boost circuitry 222, and the disconnect of the boost circuitry 222 upon the return of the SLEW ENABLE signal to an inactive state.

At S710, an ENABLE signal, for example, the ENABLE signal 230, is received by a low-power and fast wake-up band-gap reference voltage circuit, e.g., 200A or 200B. In an embodiment, V_{DD} may be supplied to certain components that relate to the steady-state operation of the low-power and fast wake-up band-gap reference voltage circuit prior to S710.

At S720, in response to receipt of the ENABLE signal, a power supply, for example V_{DD} 340, is applied to the components of the low-power and fast wake-up band-gap reference voltage circuit, e.g., 200A or 200B.

At S730, a pulse having a predetermined active time t_{SLEW}, is generated by a one-shot timer, for example one-shot timer 210. The pulse is a SLEW ENABLE signal, for example, the SLEW ENABLE signal 240.

At S740, under the control of the pulse generated at S730, a boost circuitry, for example, the boost circuitry 222, is connected (or disconnected as the case may require) to the core OTA. The Boost circuitry aimed at improving the wake-up response time of the low-power and fast wake-up band-gap reference voltage circuit, e.g., 200A or 200B, as further explained herein.

At S750, it is checked whether the pulse is still in its active state and if so, execution continues with S750, i.e., continuing to wait at the state where the boost circuitry remains connected (or disconnected as the case may require) for the duration of the pulse, i.e., its pulse width as measured in time units; otherwise, continuing with S760.

At S760, upon the pulse returning to its inactive state, the boost circuitry (or connection as the case may require) previously connected (or disconnect) for the purpose of improving the wake-up performance of the low-power and fast wake-up band-gap reference voltage circuit, e.g., 200A or 200B is disconnected.

It should be understood that once the ENABLE signal, for example, ENABLE signal 230, returns to an inactive state, V_{REF} 250 is no longer valid, and the low-power and fast wake-up band-gap reference voltage circuit is off, hence consuming zero current. That is, upon return of the ENABLE signal to an inactive state any reference voltage provided by the low-power and fast wake-up band-gap reference voltage circuit is discontinued and ceases to be valid. Furthermore, upon return of the ENABLE signal to an inactive state, any biasing currents of the low-power and fast wake-up band-gap reference voltage circuit are discontinued.

In an embodiment, a low-power fast wake-up band-gap reference voltage circuit comprises: a one-shot timer that generates a slew enable signal pulse for a predetermined period of time upon receipt of an enable signal; a band-gap voltage reference circuitry comprising an operational amplifier communicatively connected to the one-shot timer, a current mirror circuitry, a plurality of compensation capacitors, and a plurality of resistors, wherein the band-gap voltage reference circuitry is adapted to operate at a dormant power consumption level or at a steady-state power consumption level when providing a reference voltage after activation of the enable signal, wherein the steady-state power consumption is higher than the dormant power consumption; and, a boost circuitry communicatively connected to the band-gap voltage reference circuitry and further communicatively connected to the one-shot timer, wherein the boost circuitry comprises one or more boost circuits that upon activation of the one-shot slew enable signal causes a connection of one or more of the one or more boost circuits to the band-gap voltage reference, that together with other circuits of the band-gap voltage reference circuitry operate at a wake-up power consumption level that is higher than the steady-state power consumption level.

In an embodiment thereof, the low-power fast wake-up band-gap reference voltage circuit is configured for a fast wake-up at the wake-up power consumption level, and, the low-power fast wake-up band-gap reference voltage circuit operates at the steady-state power consumption level upon deactivation of the one-shot slew enable signal that results in disconnect of the boost circuitry.

In another embodiment, a method of operation of a low-power fast wake-up band-gap reference voltage circuit comprises: operating the low-power fast wake-up band-gap reference voltage circuit at a dormant power consumption level; receiving by the low-power fast wake-up band-gap reference voltage circuit an enable signal; supplying a wake-up power to the low-power fast wake-up band-gap reference voltage circuit upon receipt of the enable signal; generating a pulse signal of a first pulse width upon receipt of the enable signal; connecting under control of the pulse and for a duration of the first pulse width a boost circuitry of the low-power fast wake-up band-gap reference voltage circuit that comprises one or more boost circuits that cause the low-power fast wake-up band-gap reference voltage circuit to operate at the wake-up power level consumption that is higher than the wake-up level of power consumption; and, disconnecting the boost circuitry under control of the pulse signal so that the low-power fast wake-up band-gap reference voltage circuit consumes power at a steady-state level of power consumption which is lower than the wake-up power consumption and higher than the dormant power consumption.

All examples and conditional language recited herein are intended for pedagogical purposes to aid the reader in understanding the principles of the disclosed embodiment and the concepts contributed by the inventor to furthering the art and are to be construed as being without limitation to such specifically recited examples and conditions. Moreover, all statements herein reciting principles, aspects, and embodiments of the disclosed embodiments, as well as specific examples thereof, are intended to encompass both structural and functional equivalents thereof. Additionally, it is intended that such equivalents include both currently known equivalents as well as equivalents developed in the future, i.e., any elements developed that perform the same function, regardless of structure.

It should be understood that any reference to an element herein using a designation such as “first,” “second,” and so forth does not generally limit the quantity or order of those elements. Rather, these designations are generally used herein as a convenient method of distinguishing between two or more elements or instances of an element. Thus, a reference to first and second elements does not mean that only two elements may be employed there or that the first element must precede the second element in some manner. Also, unless stated otherwise, a set of elements comprises one or more elements.

As used herein, the phrase “at least one of” followed by a listing of items means that any of the listed items can be utilized individually, or any combination of two or more of the listed items can be utilized. For example, if a system is described as including “at least one of A, B, and C,” the system can include A alone; B alone; C alone; 2A; 2B; 2C; 3A; A and B in combination; B and C in combination; A and C in combination; A, B, and C in combination; 2A and C in combination; A, 3B, and 2C in combination; and the like.

What is claimed is:

1. A low-power fast wake-up band-gap reference voltage circuit comprising:
a one-shot timer that generates a slew enable signal for a predetermined period of time upon receipt of an enable signal;
a band-gap voltage reference circuitry comprising an operational amplifier communicatively connected to the one-shot timer, a current mirror circuitry, a plurality of compensation capacitors, and a plurality of resistors, wherein the band-gap voltage reference circuitry is adapted to operate at a dormant power consumption level or at a steady-state power consumption level when providing a reference voltage after activation of the enable signal, wherein the steady-state power consumption level is higher than the dormant power consumption level; and,
a boost circuitry communicatively connected to the band-gap voltage reference circuitry and further communicatively connected to the one-shot timer, wherein the boost circuitry comprises one or more boost circuits that upon activation of the one-shot slew enable signal cause a connection of one or more of the one or more boost circuits to the band-gap voltage reference circuitry, that together with other circuits of the band-gap voltage reference circuitry operate at a wake-up power consumption level that is higher than the steady-state power consumption level;
wherein the low-power fast wake-up band-gap reference voltage circuit is configured for a fast wake-up at the wake-up power consumption level, and,
wherein the low-power fast wake-up band-gap reference voltage circuit operates at the steady-state power consumption level upon deactivation of the one-shot slew enable signal that disconnects the boost circuitry.

2. The circuit of claim 1, wherein the predetermined period of time is programmable.

3. The circuit of claim 1, wherein the predetermined period of time ranges between 1 μs and 3 μs.

4. The circuit of claim 1, wherein a circuit of the one or more boost circuits comprises a current source activated by the slew enable signal.

5. The circuit of claim 1, wherein a circuit of the one or more boost circuits comprises one or more transistors that when connected to the band-gap voltage reference circuitry accept therethrough excess current while the slew enable signal pulse is active.

6. The circuit of claim 1, wherein a circuit of the one or more boost circuits comprises a filter to suppress oscillations of the reference voltage while the slew enable signal pulse is active.

7. A method of operation of a low-power fast wake-up band-gap reference voltage circuit, the method comprises:
operating the low-power fast wake-up band-gap reference voltage circuit at a dormant power consumption level;
receiving by the low-power fast wake-up band-gap reference voltage circuit an enable signal;
supplying a wake-up power to the low-power fast wake-up band-gap reference voltage circuit upon receipt of the enable signal;
generating a pulse signal of a first pulse width upon receipt of the enable signal;
connecting under control of the pulse signal and for a duration of the first pulse width a boost circuitry of the low-power fast wake-up band-gap reference voltage circuit that comprises one or more boost circuits that cause the low-power fast wake-up band-gap reference voltage circuit to operate at a wake-up power level consumption that is higher than the wake-up power level consumption; and,
disconnecting the boost circuitry under control of the pulse signal so that the low-power fast wake-up band-gap reference voltage circuit consumes power at a steady-state level of power consumption which is lower than the wake-up power level consumption and higher than the dormant power consumption level.

8. The method of claim 7, wherein the pulse signal is a slew enable signal.

9. The method of claim 7, wherein the first pulse width is programmable.

10. The method of claim 7, wherein the first pulse width is between 1 μs and 3 μs.

11. The method of claim 7, wherein generating the pulse signal is performed by a one-shot timer.

12. The method of claim 7, wherein a circuit of the one or more boost circuits comprises a current source activated by the enable signal.

13. The method of claim 7, wherein a circuit of the one or more boost circuits comprises one or more transistors that, when connected to the wake-up band-gap reference voltage circuit, accept therethrough excess current while the enable signal is active.

14. The method of claim 7, wherein a circuit of the one or more boost circuits comprises a filter to suppress oscillations of the low-power fast wake-up band-gap reference voltage while the enable signal pulse is active.

15. The method of claim 7, further comprises:
discontinuing at least a reference voltage upon return of the enable signal to an inactive state.

16. The method of claim 7, further comprises:
discontinuing at least a biasing current upon return of the enable signal to an inactive state.
